(19) United States
(12) Patent Application Publication
(10) Pub. No.: US 2018/0138333 A1
(43) Pub. Date: May 17, 2018

(54) METHOD OF FORMING AN ELECTRODE STRUCTURE AND METHOD OF MANUFACTURING A PHOTOVOLTAIC CELL USING THE SAME

(71) Applicant: Korea University Research and Business Foundation, Seoul (KR)

(72) Inventors: Joo Youl Huh, Seoul (KR); Hee Soo Kim, Seoul (KR); Sung Bin Cho, Gyeonggi-do (KR)

(73) Assignee: Korea University Research and Business Foundation, Seoul (KR)

(21) Appl. No.: 15/711,683

(22) Filed: Sep. 21, 2017

(30) Foreign Application Priority Data
Sep. 21, 2016 (KR) 10-2016-0120455

(51) Int. Cl. H01L 31/0224; H01L 31/18

(52) U.S. Cl. CPC H01L 31/022425; H01L 31/022475; H01L 31/1884; H01L 31/1804

(57) ABSTRACT

In a method of forming an electrode structure for a photovoltaic cell, a transparent conductive layer is formed on a semiconductor layer of amorphous silicon material doped with dopants of a first conductive type. Then, a first metal pattern is formed on the transparent conductive layer by performing an ink jet process using metal nano ink. After forming a metal paste layer using a conductive paste through a screen printing process to cover the first metal pattern, the metal paste layer is fired to transform the metal paste layer into a second metal pattern such that the first and the second metal patterns are formed on the transparent metal layer to define a metal electrode.

### PRIORITY STATEMENT

This application claims priority under 35 U.S.C. § 119 to Korean Patent Application No. 10-2016-0120455, filed on Sep. 21, 2016 in the Korean Intellectual Property Office (KIPO), the contents of which application are herein incorporated by reference in their entirety.

### BACKGROUND

### 1. Field of Disclosure

The present document relates to a method of forming an electrode structure and a method of manufacturing a photovoltaic cell using the same. More specifically, the present document relates to a method of forming an electrode structure on a semiconductor layer, and a method of manufacturing a photovoltaic cell using the method of forming an electrode structure.

### 2. Description of Related Technology

As existing fossil energy resources such as petroleum and coal have depleted, Fukushima nuclear power plant accident occurred, and global warming problem has become serious, there have been research and development on energy sources that can substitute the fossil energy resources with a safe energy sources and can reduce environmental pollution. Specially, Researchers have focused on solar energy development in which solar light can utilized indefinitely.

A photovoltaic cell using solar light is a device that converts light energy into electrical energy by using photovoltaic effect, and silicon solar cell is representative.

In general, the silicon solar cell includes p-type and n-type semiconductor layers. Further, the silicon solar cell includes a rear electrode and a front electrode such that electrons and holes generated by light irradiation are to be collected at both electrodes to generate electromotive force.

In recent years, studies have been made on an n-type silicon cell having an n-type silicon substrate instead of a conventional p-type silicon as a substrate. In this case, the n-type silicon substrate has advantages such that the degradation due to light irradiation is relatively small and sensitivity to impurities is relatively low, so that the silicon solar cell can be realized with an improved efficiency.

The n-type silicon solar cell forms a p-type conductive layer by doping a surface portion of the n-type silicon substrate with a group III element such as born (B), aluminum (Al), or gallium (Ga) to transform the surface portion of the n-type silicon substrate into a p-type semiconductor layer to form a p-n junction. At this case, the p-type semiconductor layer for forming the p-n junction may include an amorphous silicon material. As a result, since the amorphous silicon material has a band gap larger than that of the crystalline silicon material, a passivation property may be excellent and a relatively high open-circuit voltage (Voc) can be secured.

However, when the solar cell includes the amorphous silicon semiconductor layer made of the amorphous silicon material, the amorphous silicon semiconductor layer has a relatively low electrical conductivity, and thus, it should be required to further form a transparent conductive oxide (TCO) layer on the amorphous silicon semiconductor layer. In addition, the amorphous silicon material may have thermal damage due to crystallization in a subsequent firing process for forming a metal electrode using the metal paste. Thus, when the metal electrode is formed on top of the transparent conductive oxide (TCO) layer which is formed on the amorphous silicon semiconductor layer, a low-temperature firing process is required.

Further, a low line resistance and a low contact resistance between the transparent conductive oxide (TCO) layer and the metal electrode are also required. Specially while performing the low-temperature firing process, problem may occur that voids are generated at an interface portion between the metal electrode and the transparent conductive oxide layer, which may cause a contact resistance to increase.

### SUMMARY

One object of the present solution is to provide a method of forming an electrode structure including a metal electrode formed on a transparent conductive layer of a transparent conductive oxide, capable of having a relatively low contact resistance and securing an excellent adhesive force, and a high aspect ratio.

Another object of the present solution is to provide a method of manufacturing a photovoltaic cell capable of realizing a front electrode having a low contact resistance and a low line resistance by using the above-described electrode structure.

In some scenarios of the present solution, in a method of forming an electrode structure for a photovoltaic cell, a transparent conductive layer is formed on a semiconductor layer of amorphous silicon material doped with dopants of a first conductive type. Then, a first metal pattern is formed on the transparent conductive layer by performing an ink jet process using metal nano ink. After forming a metal paste layer using a conductive paste through a screen printing process to cover the first metal pattern, the metal paste layer is fired to transform the metal paste layer into a second metal pattern such that the first and the second metal patterns are formed on the transparent metal layer to define a metal electrode.

In those or other scenarios, performing the ink jet process may include applying a metal nano ink onto the transparent conductive layer to form a nano ink layer on the transparent conductive layer, and removing an organic solvent from the nano ink layer.

In those or other scenarios, the conductive paste may include a metal powder, a conductive polymer and an organic solvent.

In those or other scenarios, the metal paste layer may be formed to cover both a side face and an upper face of the first metal pattern.

In those or other scenarios, firing the metal paste layer may include performing a firing process at a temperature of under about 230° C.

According to the present solution, in a method of manufacturing a photovoltaic cell, an amorphous silicon semiconductor layer is deposited on a crystalline silicon layer to form a p-n junction. After forming a transparent conductive layer on the amorphous silicon semiconductor layer, a first metal pattern is formed on the transparent conductive layer by performing an ink jet process using metal nano ink. Then, a metal paste layer is formed using a conductive paste through a screen printing process to cover the first metal pattern. The metal paste layer is fired to transform the metal paste layer into a second metal pattern such that the first and the second metal patterns are formed on the transparent metal layer to define a metal electrode.

In some scenarios, performing the ink jet process may include applying a metal nano ink onto the transparent conductive layer to form a nano ink layer on the transparent conductive layer, and removing an organic solvent from the nano ink layer.

In those or other scenarios, the conductive paste may include a metal powder, a conductive polymer and an organic solvent.

In those or other scenarios, the metal paste layer may be formed to cover both a side face and an upper face of the first metal pattern.

In those or other scenarios, firing the metal paste layer may include performing a firing process at a temperature of under about 230° C.

According to the present solution, the electrode structure includes the first metal pattern formed by the inkjet printing process, and the second metal pattern formed through the screen printing process and the low-temperature firing process, thereby securing a relatively low contact resistance and line resistance. Further, excellent adhesion with the transparent conductive film can be ensured. In addition, the electrode structure can be easily formed through the inkjet printing process, the screen printing process, and the firing process. On the other hand, crystallization of the semiconductor layer made of amorphous silicon, which is the underlying film, can be suppressed, while forming the second metal pattern by firing the metal paste layer at a relatively low temperature.

### BRIEF DESCRIPTION OF THE DRAWINGS

The above and other features and advantages will become more apparent by describing exemplary embodiments thereof with reference to the accompanying drawings.

FIG. 1 is a flow chart illustrating a method of forming an electrode structure.

FIG. 2 is a cross-sectional view illustrating an electrode structure formed by the method of forming the electrode structure in FIG. 1.

FIGS. 3A, 3B, 3C and 3D are the scanning electron microscope images showing a difference in cross-sectional microstructure between the electrodes structures without the first metal pattern (a) & (b) and with the first metal pattern (c) & (d) formed by the method of forming the electrode structure.

FIG. 4 is a flow chart illustrating a method of manufacturing a photovoltaic cell.

### DETAILED DESCRIPTION

Hereinafter, embodiments of the invention will be explained in detail with reference to the accompanying drawings. While the invention is susceptible to various changes have to be introduced in various forms and may have a bar, and the specific embodiments illustrated in the drawings shall be explained in detail in the text. However, it is disclosed in a particular form of the present invention is not intended to limit, the spirit and technical scope of the present invention includes all modifications, equivalents and substitutes should be understood to include. Accompanying drawings, the dimensions of the structure of the present invention larger than actual in order to clarity the group shown in the drawings.

The terms such as first, second, etc., can be used in describing various elements, but the above elements by the above terms should not be limited. The above terms are one element from the other used only to distinguish. For example, in the present invention without departing from the scope of the first component to the second component may be named similarly, the second component to the first component also can be named.

Use of a term in the present application for the purpose of describing particular embodiments only be used, and are not intended to limit the invention. Yield a clearly different meaning in the context of the expression of the plural, unless expressed and the like. In the present application, “including” or “having” and the like is intended to set forth features, integers, steps, operations, elements, parts or combinations not possible specify the presence of one or more other features, integers, steps, operations, elements, parts or combinations of those present in or added are not intended to preclude the possibility must be.

Unless otherwise defined, including technical and scientific terms used herein, all terms are to the present invention is not skilled in the art as commonly understood by one party the same meaning. The commonly used terms such as those defined in advance in the context of the related art having the meanings and shall be construed to have a meaning consistent and, in this application, unless otherwise defined explicitly, ideal or excessively formal meaning to be construed not.

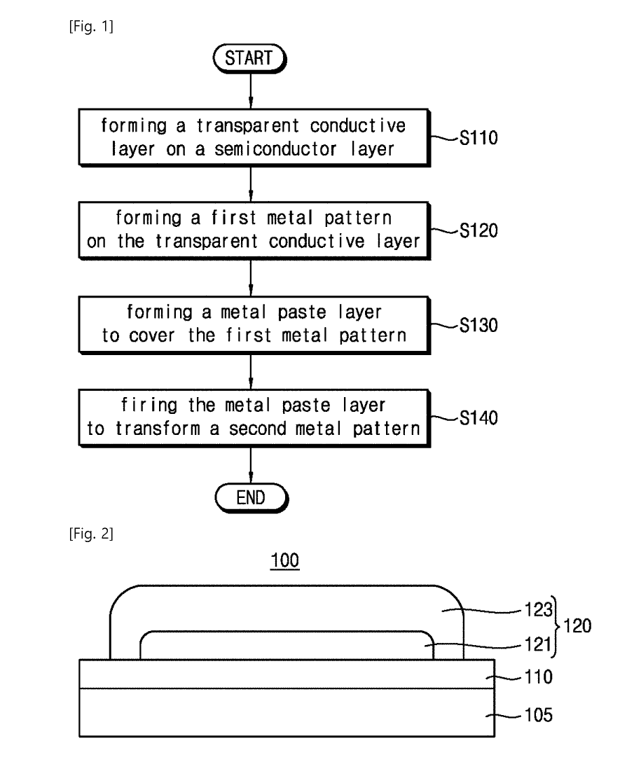

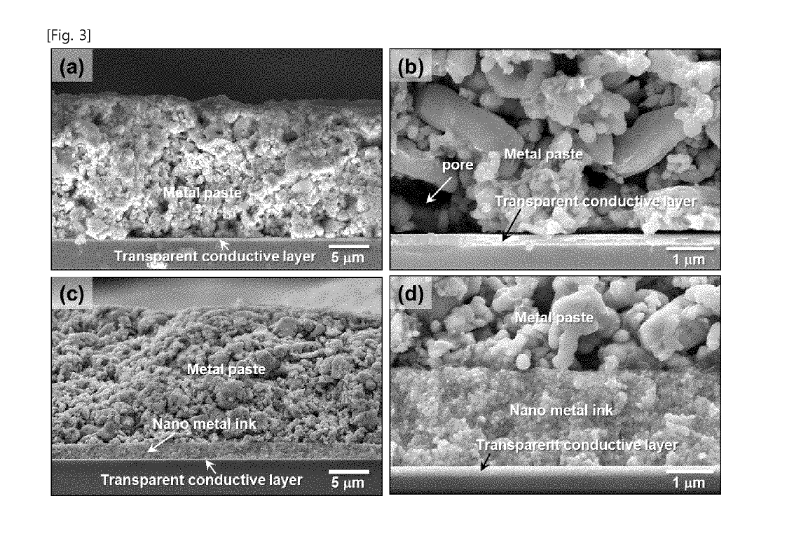

FIG. 1 is a flow chart illustrating a method of forming an electrode structure according to an illustration of the present solution. FIG. 2 is a cross-sectional view illustrating an electrode structure formed by the method of forming the electrode structure in FIG. 1.

Referring to FIGS. 1 and 2, a transparent conductive layer 110 is formed on a semiconductor layer 105 made of amorphous silicon material doped with a first conductive type dopant (S110). The first conductive type dopants may be n-type or p-type dopants. Accordingly, the semiconductor layer 105 may correspond to an n-type semiconductor layer or a p-type semiconductor layer.

The semiconductor layer 105 is formed to have an amorphous silicon layer through a deposition process. Further, it is required to suppress the semiconductor layer 105 from changing from the amorphous structure into a (poly) crystalline structure due to a crystallization of the amorphous structure in a subsequent heat treatment process, for example, a firing process. That is, in the heat treatment process, it is required that the property deterioration due to crystallization of the semiconductor layer 105 is suppressed.

Here, a transparent conductive layer 110 is formed using indium-tin oxide, aluminum-doped zinc oxide, boron-doped zinc oxide, or the like. By forming the transparent conductive layer 110 on the semiconductor layer 105, the electrode structure 100 may have an improved electrical conductivity, comparing with an electrode structure without the transparent conductive layer 110.

Next, a first metal pattern 121 is formed on the transparent conductive layer 110 through an inkjet printing process using a nano metal ink (S120). That is, the first metal pattern 121 can be easily formed through the inkjet printing process. In addition, a contact resistance of a metal electrode to the transparent conductive layer 110 can be reduced by applying the first metal pattern 121.

In the inkjet process for forming the first metal pattern 121, a nano metal ink may include metal nano powders and an organic solvent. According to the inkjet printing process using the nano ink, a nano ink layer (not shown) is formed by applying the nano metal ink onto the transparent conductive layer 110. Then, the first metal pattern 121 is formed on the transparent conductive layer 110 by removing the organic solvent from the nano ink layer through a drying process.

Next, a metal paste layer is formed using a conductive paste to cover the first metal pattern 121 (S130). The conductive paste includes a metal powder, a conductive polymer, and an organic solvent. The metal powder includes, for example, silver, aluminum, nickel, copper, tin, or the like. Thus, a second metal pattern 123 to be formed by firing the conductive paste layer can secure an improved electrical conductivity of the electrode structure 100.

Specially, the conductive polymer may help to maintain a shape of the second metal pattern formed through a subsequent firing process. Further, the conductive polymer may increase an adhesive force between the second metal pattern and the transparent conductive layer after the firing process.

The metal paste layer may be formed to cover a side face and an upper face of the first metal pattern 121 as a whole. That is, since the metal paste layer covers the first metal pattern 121 entirely, the second metal pattern 123 which is to be transformed from the metal paste layer is more strongly adhered to the first metal pattern 121, thereby reducing the contact resistance between the first and second metal patterns 121 and 123.

Further, the metal paste layer is formed through a screen printing process. Therefore, a patterning process, which might be required for forming the second metal pattern 123, may be omitted. Further, the second metal pattern 123 transformed from the metal paste layer may have a relatively low line resistance owing to the conductive polymer.

Then, the metal paste layer is fired to convert the metal paste layer into the second metal pattern 123 to form a metal electrode 120 including the first and second metal patterns 121 and 123 on the transparent conductive layer 110 (S140). The firing process for firing the metal paste layer may be performed at a relatively low temperature below 230° C. Thus, the amorphous silicon material contained in the semiconductor layer 105 underneath the transparent conductive layer 110 can be suppressed from crystallizing. As a result, deterioration of electrical characteristics due to crystallization of the semiconductor layer 105 can be suppressed.

According to the present solution, the electrode structure 100 includes the first metal pattern 121 formed by the inkjet printing process and the second metal pattern 123 formed by the screen printing process and the low-temperature firing process. Thus, a low contact resistance and a low line resistance can be ensured and excellent adhesion of the metal electrode 120 to the transparent conductive layer 110 can be ensured. In addition, the electrode structure 100 can be easily formed through an inkjet printing process and a screen printing process. On the other hand, crystallization of the semiconductor layer 110 made of amorphous silicon material, which is positioned below the metal paste layer, can be suppressed, while firing the metal paste layer at a relatively low temperature for forming the second metal pattern 123 from the metal paste layer.

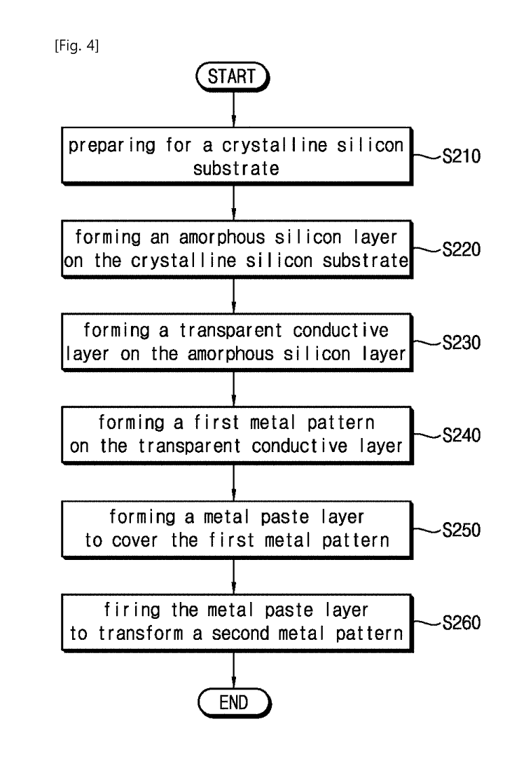

FIG. 3 depicts a difference in contact microstructure between the electrodes structures without the first metal pattern (a) & (b) and with the first metal pattern (c) & (d) formed by the method of forming the electrode structure

Referring to FIG. 3, (a) and (b) show an electrode structure where a second metal pattern was formed directly on an indium-tin oxide (ITO) transparent conductive layer, and a large number of voids existed at an interface between the transparent conductive layer and the second metal pattern. Thus, a contact resistance between the transparent conductive layer and the second metal pattern can be increased. On the other hand, in the case of (c) and (d), the electrode structure having the first and second metal patterns on the ITO transparent conductive layer was formed, and no voids were observed at the interface between the transparent conductive layer and the metal electrode. Thus, the contact resistance between the transparent conductive layer and the electrode can be expected to be reduced.

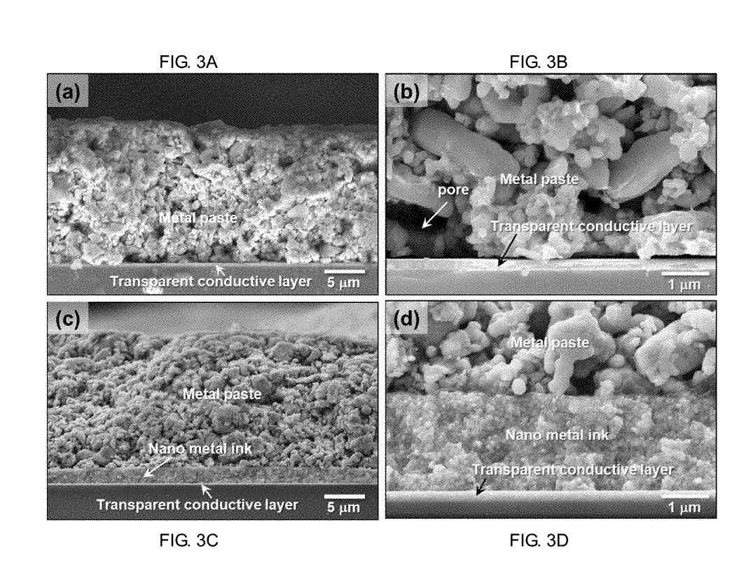

FIG. 4 is a flow chart illustrating a method of manufacturing a photovoltaic cell according to the present solution.

Referring to FIGS. 2 and 4, an n-type or p-type crystalline silicon substrate is prepared (S210).

Next, an intrinsic amorphous silicon layer and an extrinsic amorphous silicon layer doped with first type dopants are sequentially formed on the crystalline silicon substrate through a deposition process (S220). The first type dopants may correspond to Group III elements when the crystalline silicon substrate is n-type, whereas may correspond to Group V elements when the crystalline silicon substrate is p-type. As a result, the crystalline silicon substrate and the amorphous silicon semiconductor layer form a p-n junction.

Then, a transparent conductive layer is formed on the amorphous silicon layer doped with the first-type dopants (S230).

The transparent conductive layer may be formed using indium-tin oxide, aluminum-doped zinc oxide, boron-doped zinc oxide, or the like. By forming the transparent conductive layer on the amorphous silicon layer, an electrical conductivity can be improved

Next, a first metal pattern 121 is formed on the transparent conductive layer 110 through an inkjet printing process using a nano metal ink (S240). That is, the first metal pattern 121 can be easily formed through the inkjet printing process. In addition, a contact resistance of a metal electrode to the transparent conductive layer 110 can be reduced by applying the first metal pattern 121.

In the inkjet process for forming the first metal pattern 121, a nano metal ink including metal nano powders and an organic solvent may be used. According to the inkjet printing process using the nano ink, a nano ink layer (not shown) is formed by applying the nano metal ink onto the transparent conductive layer 110. Then, the first metal pattern 121 is formed on the transparent conductive layer 110 by removing the organic solvent from the nano ink layer through a drying process.

Next, a metal paste layer is formed using a conductive paste to cover the first metal pattern 121 (S250). The conductive paste includes a metal powder, a conductive polymer, and an organic solvent. The metal powder may be, for example, silver, aluminum, nickel, copper, tin, or the like. Thus, a second metal pattern to be formed by firing the conductive paste layer can secure an improved electrical conductivity.

Specially, the conductive polymer may help to maintain a shape of the second metal pattern formed through a subsequent firing process to maintain. Further, the conductive polymer may increase an adhesive force between the second metal pattern and the transparent conductive layer after the firing process.

The metal paste layer may be formed to cover a side face and an upper face of the first metal pattern 121 as a whole. That is, since the metal paste layer covers the first metal pattern 121 entirely, the second metal pattern 123 which is to be transformed from the metal paste layer is more strongly adhered to the first metal pattern 121, thereby reducing the contact resistance between the first and second metal patterns 121 and 123.

Further, the metal paste layer is formed through a screen printing process. Therefore, a patterning process, which might be required for forming the second metal pattern 123, may be omitted. Further, the second metal pattern 123 transformed from the metal paste layer may have a relatively low line resistance owing to the conductive polymer.

Then, the metal paste layer is fired to convert the metal paste layer into the second metal pattern 123 to form a metal electrode 120 including the first and second metal patterns 121 and 123 on the transparent conductive layer 110 (S260). The firing process for sintering the metal paste layer may be performed at a relatively low temperature below 230° C. Thus, the amorphous silicon material contained in the semiconductor layer 105 underneath the transparent conductive layer 110 can be suppressed from crystallizing. As a result, deterioration of electrical characteristics due to crystallization of the semiconductor layer 105 can be suppressed.

Further, a back surface field (BSF) layer and a rear surface electrode are sequentially formed on a lower face of the crystalline silicon substrate to manufacture a photovoltaic cell.

In some scenarios, the method of forming an electrode structure and the method of manufacturing a photovoltaic cell can be adapted to a method of manufacturing an amorphous silicon photovoltaic cell.

The foregoing is illustrative of the present teachings and is not to be construed as limiting thereof. Although a few exemplary embodiments have been described, those skilled in the art will readily appreciate from the foregoing that many modifications are possible in the exemplary embodiments without materially departing from the novel teachings and advantages of the present disclosure of invention. Accordingly, all such modifications are intended to be included within the scope of the present teachings. In the claims, means-plus-function clauses are intended to cover the structures described herein as performing the recited function and not only structural equivalents but also functionally equivalent structures.

What is claimed is:

1. A method of forming an electrode structure for a photovoltaic cell, comprising:
forming a transparent conductive layer on a semiconductor layer of amorphous silicon material doped with dopants of a first conductive type;
forming a first metal pattern on the transparent conductive layer by performing an ink jet process using metal nano ink;
forming a metal paste layer using a conductive paste through a screen printing process to cover the first metal pattern; and
firing the metal paste layer to transform the metal paste layer into a second metal pattern such that the first and the second metal patterns are formed on the transparent metal layer to define a metal electrode.

2. The method of claim 1, wherein performing the ink jet process comprise:
applying a metal nano ink onto the transparent conductive layer to form an nano ink layer on the transparent conductive layer; and
removing an organic solvent from the nano ink layer.

3. The method of claim 1, wherein the conductive paste includes a metal powder, a conductive polymer, and an organic solvent.

4. The method of claim 1, wherein the metal paste layer is formed to cover both a side face and an upper face of the first metal pattern.

5. The method of claim 1, wherein firing the metal paste layer includes performing a firing process at a temperature of under about 230° C.

6. A method of manufacturing a photovoltaic cell, comprising:
depositing an amorphous silicon semiconductor layer on a crystalline silicon layer to form a p-n junction;
forming a transparent conductive layer on the amorphous silicon semiconductor layer;
forming a first metal pattern on the transparent conductive layer by performing an ink jet process using metal nano ink;
forming a metal paste layer using a conductive paste through a screen printing process to cover the first metal pattern; and
firing the metal paste layer to transform the metal paste layer into a second metal pattern such that the first and the second metal patterns are formed on the transparent metal layer to define a metal electrode.

7. The method of claim 6, wherein performing the ink jet process comprise:
applying a metal nano ink onto the transparent conductive layer to form an nano ink layer on the transparent conductive layer; and
removing an organic solvent from the nano ink layer.

8. The method of claim 6, wherein the conductive paste includes a metal powder, a conductive polymer, and an organic solvent.

9. The method of claim 6, wherein the metal paste layer is formed to cover both a side face and an upper face of the first metal pattern.

10. The method of claim 6, wherein firing the metal paste layer includes performing a firing process at a temperature of under about 230° C.
